(19) United States
(12) Patent Application Publication
(10) Pub. No.: US 2025/0156041 A1
(43) Pub. Date: May 15, 2025

(54) DISPLAY DEVICE

(71) Applicant: DMG MORI CO., LTD., Nara (JP)

(72) Inventors: Shingo SEKISAWA, Kanagawa (JP); Hideo MAEJIMA, Kanagawa (JP); Toyohiko MATSUDA, Kanagawa (JP)

(73) Assignee: DMG MORI CO., LTD., Nara (JP)

(21) Appl. No.: 18/833,915

(22) PCT Filed: Sep. 4, 2023
(86) PCT No.: PCT/JP2023/032169

§ 371 Date: Jul. 28, 2024

(30) Foreign Application Priority Data
Sep. 9, 2022 (JP) 2022-143589

(51) Int. Cl. G06F 3/0484; G06F 3/04886

(52) U.S. Cl. CPC G06F 3/0484; G06F 3/04886

(57) ABSTRACT

A display device includes a display unit and a display control unit that controls images displayed on the display unit. When one of a plurality of modes with mutually different ways of displaying measurement results is selected by using a mode button displayed on the display unit, the display control unit displays a measurement result on the display unit in a mode corresponding to the selected mode. The plurality of modes include at least, (i) a dial mode that displays an image of a scale and a pointer superimposed thereon to display a value indicated by the pointer, and (ii) a numeric mode that displays at least a measurement value, the maximum measurement value within a given period, and the minimum measurement value within the given period.

### TECHNICAL FIELD

This invention relates to image display technology and more particularly to image display technology in measuring instruments.

### BACKGROUND ART

Measuring instruments, such as dial gauges, are equipped with physically displaceable sensor members called spindles and levers. A dial gauge indicates the displacement amount of the sensor member by means of a pointer. Patent Literature 1 describes a measuring instrument capable of displaying the displacement amount of a spindle as an image.

### RELATED ART LIST

Patent Literature 1: JP 2013-185990 A
Patent Literature 2: JP H08-061907 A

### SUMMARY

### Technical Problem

When measurement results are displayed as digital images, it is desirable to display the measurement values in an appropriate manner according to the purpose of measurement. In the case of a lever gauge, since there is a range where the measurement accuracy is relatively high and a range where the accuracy is low due to the characteristics of the structure, it is desirable to measure the displacement amount of the lever gauge in the range where the measurement accuracy is high.

### Solution to Problem

A display device in one aspect of the invention includes a display unit and a display control unit that controls images displayed on the display unit.

When one of a plurality of modes with mutually different ways of displaying measurement results is selected by using a mode button displayed on the display unit, the display control unit displays a measurement result on the display unit in a mode corresponding to the selected mode.

The plurality of modes include at least:
(i) a dial mode that displays an image of a scale and a pointer superimposed thereon to display a value indicated by the pointer; and
(ii) a numeric mode that displays at least a measurement value, the maximum measurement value within a given period, and the minimum measurement value within the given period.

A display device in another aspect of the invention includes a display unit that displays displacement amount of a variable lever as a measurement value, and a display control unit that controls images displayed on the display unit.

The lever has a valid measurement range set as a predetermined measurement range that includes a reference position that is different from an initial position and that corresponds to a reference displacement amount.

The display control unit causes an indicator showing the valid measurement range to be displayed and indicates whether or not the current displacement amount of the lever is within the valid measurement range.

### Advantageous Effects of Invention

The present invention can easily improve the visibility of measurement results.

### BRIEF DESCRIPTION OF DRAWINGS

FIG. 1 is a perspective view of a lever gauge.

FIG. 2A is a top view of a display device. FIG. 2B is a front view of the display device. FIG. 2C is a side view of the display device.

FIG. 3 is a perspective view of the display device.

FIG. 4 is a schematic diagram illustrating a measurement method of a circular structure using a lever gauge.

FIG. 5 is a functional block diagram of the display device.

FIG. 6 is a first screen view of a dial mode screen.

FIG. 7 is a second screen of the dial mode screen.

FIG. 8 is a screen view of a bar mode screen.

FIG. 9 is a screen view of a numeric mode screen.

FIG. 10 is a screen view of a chart mode screen.

FIG. 11 is a screen view of a circularity measurement mode screen.

FIG. 12 is a schematic diagram to explain the movable range of a lever in a lever gauge.

FIG. 13 illustrates an example of the display of an indicator during reference position exploration.

### DESCRIPTION OF EMBODIMENTS

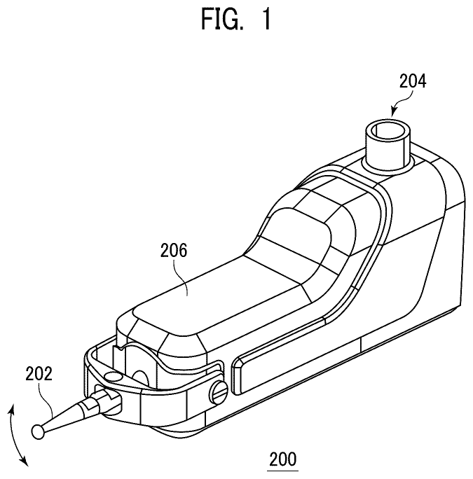

FIG. 1 is a perspective view of a lever gauge 200.

The lever gauge 200 includes a body part 206, a connection terminal 204, and a lever 202 configured to be displaceable. The lever 202 is vertically displaceable, as indicated by the arrow in FIG. 1. The lever gauge 200 is a measuring instrument that measures the physical displacement amount of the lever 202. The lever gauge 200 is connected to a display device 100 described below via the connection terminal 204. The lever gauge 200 generates an electrical signal indicating the displacement amount of the lever 202 (hereinafter referred to as “displacement signal”) and transmits the signal from the connection terminal 204 to the display device 100.

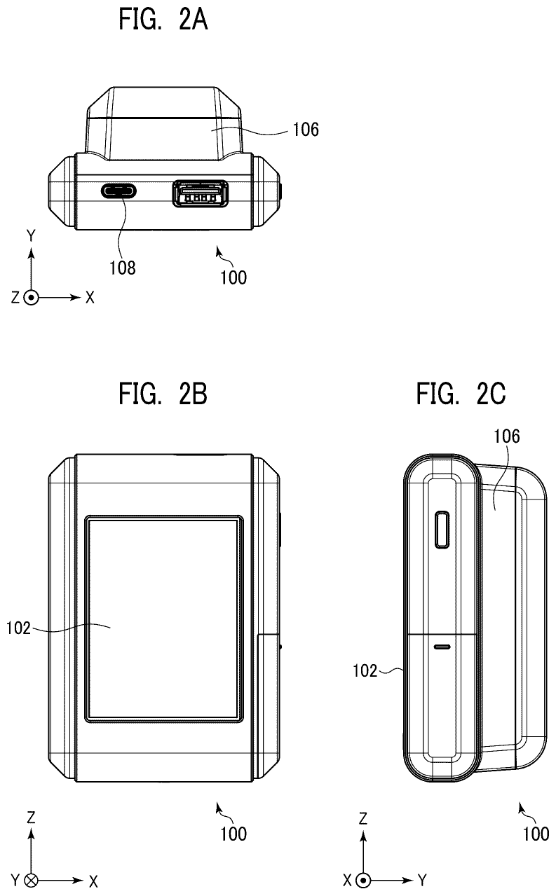

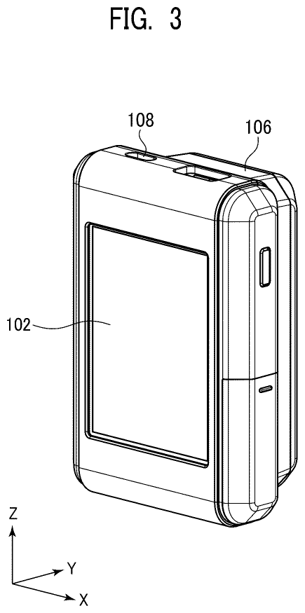

FIG. 2A is a top view of the display device 100, FIG. 2B is a front view of the display device 100, and FIG. 2C is a side view of the display device 100. FIG. 3 is a perspective view of the display device 100.

The following description is based on the X-, Y-, and Z-axes shown in FIGS. 2A through 2C and FIG. 3. The Z-axis direction is assumed to be vertical, and the X-axis and Y-axis directions are assumed to be horizontal.

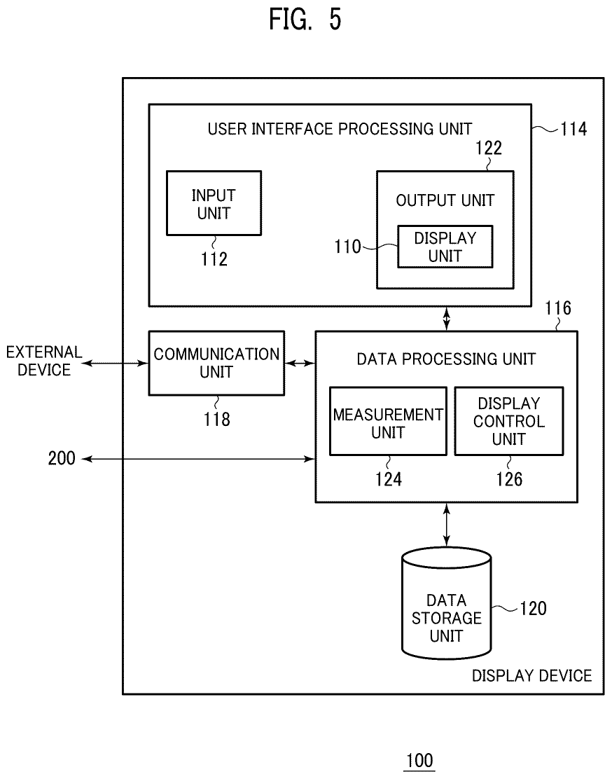

The display device 100 is equipped with a monitor 102 as a full-color LCD (Liquid Crystal Display). Measurement values received as displacement signals from the lever gauge 200 are displayed on the monitor 102. The monitor 102 corresponds to the display unit 110 in FIG. 5. A touch panel is installed on the surface of the monitor 102, and the user can operate the display device 100 via the touch panel. This touch panel corresponds to the input unit 112 in FIG. 5.

As shown in FIG. 2B, a USB (Universal Serial Bus) terminal 108 is provided on the upper (first) side of the display device 100. The display device 100 is connected to the lever gauge 200 via a cable by means of the USB terminal 108. The back portion 106 houses a rechargeable battery, which is not shown in the figures.

The display device 100 can communicate with external devices via Bluetooth (registered trademark). The display device 100 is also equipped with a micro SD card insertion slot and the like. The display device 100 can also store measurement values on a micro SD card. It is also possible to update firmware by using the micro SD card. The body of the display device 100 is made of resin. The back portion 106 incorporates a steel plate so that the back portion 106 can be attached to a magnet.

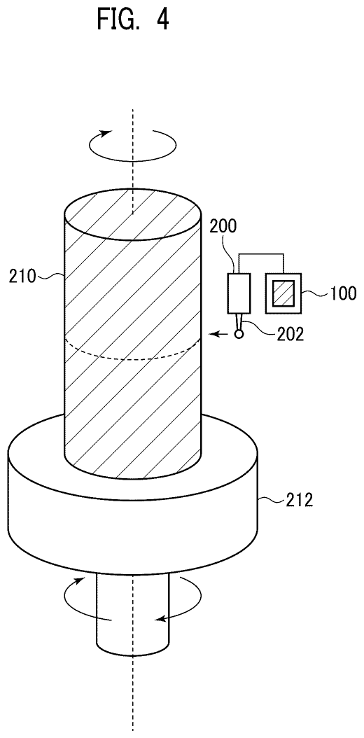

FIG. 4 is a schematic diagram illustrating a measurement method of a circular structure 210 using a lever gauge 200.

The circular structure 210 is a workpiece to be measured and has a cylindrical shape. In FIG. 4, the lever gauge 200 measures the “circularity” of the circular structure 210, more specifically, the difference between the circular structure 210 and a perfect circle. First, the lever gauge 200 is fixed with the lever 202 of the lever gauge 200 pressed against the surface of the circular structure 210. The lever gauge 200 is connected to the display device 100. The circular structure 210 is placed on a rotary table 212. The rotary table 212 rotates at a constant rotational speed, causing the circular structure 210 to rotate on its axis.

If the circumference of the circular structure 210 is a perfect circle, the lever 202 will not move from its initial setting position. However, since the surface of the circular structure 210 usually has slight distortion or unevenness, the lever 202 is slightly displaced during rotation. The circularity of the circular structure 210 is measured based on the displacement history of the lever 202 during this rotation, details of which are described below.

FIG. 5 is a functional block diagram of the display device 100.

The components of the display device 100 are implemented by hardware including computing units such as central processing units (CPUs) and various co-processors, storage devices such as memories and storages, and wired or wireless communication lines that connect these units and devices, and software that is stored in the storage devices and supplies processing instructions to the computing units. Computer programs may be constituted by device drivers, operating systems, various application programs on upper layers thereof, and a library that provides common functions to these programs. Each of the blocks described below does not represent a hardware block but represents a functional block.

The display device 100 includes a user interface processing unit 114, a data processing unit 116, a communication unit 118, and a data storage unit 120.

The user interface processing unit 114 receives operations conducted by the user and performs processing related to the user interface, such as image display and audio output. The communication unit 118 performs communication with external devices via Bluetooth (registered trademark) or the like. The data processing unit 116 executes various processes based on data acquired by the user interface processing unit 114 and the communication unit 118 and data stored in the data storage unit 120. The data processing unit 116 also functions as an interface to the user interface processing unit 114, the communication unit 118, and the data storage unit 120. The data storage unit 120 stores various programs and setting data.

The user interface processing unit 114 includes an input unit 112 and an output unit 122.

The input unit 112 receives input from the user via the touch panel on the monitor 102. The output unit 122 includes a display unit 110. The display unit 110 displays various images.

The data processing unit 116 includes a measurement unit 124 and a display control unit 126.

The measurement unit 124 converts the displacement signal received from the lever gauge 200 into a measurement value. The display control unit 126 generates images and displays the images on the display unit 110.

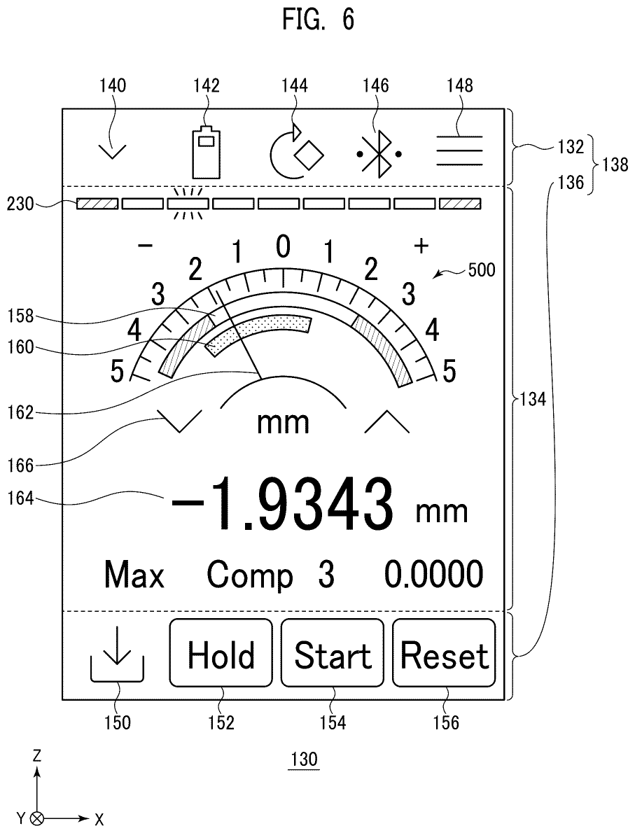

FIG. 6 is a first screen view of a dial mode screen 130.

The display control unit 126 initially displays the dial mode screen 130 on the monitor 102. The dial mode screen 130 includes an upper area 132, a measurement area 134, and a lower area 136. The measurement area 134 displays the displacement amount of the lever 202 as a measurement value by means of an image showing a meter 500 with a scale set and a pointer 162 superimposed thereon. The upper area 132 and lower area 136 are icon areas 138 for checking the status and operating the display device 100. The meter 500 includes a scale indicating the vertical displacement amount of the lever.

As shown in FIG. 6, the dial mode screen 130 is configured as a rectangular image area with the Z-axis direction as the longitudinal direction. The upper area 132 extends in the X-axis direction, and a plurality of icons (extension button 140, battery icon 142, rotation button 144, communication status icon 146, and menu button 148) are arranged along the X-axis direction. Some of the icons function as “control buttons”. The lower area 136 also extends in the X-axis direction, and a plurality of icons (save button 150, hold button 152, start button 154, and reset button 156) are arranged along the X-axis direction.

In this embodiment, the measurement area 134 is formed as a display area that is approximately square in shape. The display control 126 visually unit indicates the displacement amount of the lever 202 from the initial setting position (see below) by means of the pointer 162. For example, in a case where the initial setting position is the point where the displacement amount of the lever 202 is KX, if the displacement amount of the lever 202 is equal to KX, the pointer 162 is displayed at a position corresponding to “0,” which is the center of the meter 500. When the displacement amount of the lever 202 is larger than KX, the pointer 162 is displayed to the right of the center, and when the displacement amount of the lever 202 is less than KX, the pointer 162 is displayed to the left of the center. In FIG. 6, the pointer 162 is displayed to the left of the center, indicating that the displacement amount of the lever 202 is smaller than the initial setting position KX.

A “valid measurement range” is defined for the lever 202 as the range in which measurement accuracy can be guaranteed. The measurement range meter 158 displays a unit for the pointer 162 that indicates the distance from the initial setting position (see below). With the lever 202 of the lever gauge 200 pressed against the circular structure 210, the user checks the change in the measurement value from the initial setting position while rotating the circular structure 210 on its axis. The PP range meter 160 displays the range between minimum and maximum values in a history of changes in the measurement value. The measurement value display area 164 indicates the current measurement value, i.e., the displacement amount from the initial setting position, in numeric values. The range (scale) of the meter 500 can be changed by touching the range button 166.

When the extension button 140 in the upper area 132 is touched, the display control unit 126 displays an extended area 220 (see below). The battery icon 142 displays the remaining battery charge. When the rotation button 144 is touched, the display control unit 126 changes the display direction of the screen. The communication status icon 146 indicates the Bluetooth (registered trademark) connection status. When the menu button 148 is touched, the menu screen (not shown) is displayed.

When the save button 150 in the lower area 136 is touched, various data, such as measurement values and settings, are saved. The hold button 152 is a toggle button, and when set to the hold state, the measurement values stop being updated. The lever gauge 200 sends displacement signals to the display device 100 at regular time intervals, and the display control unit 126 updates the screen each time a new measurement value is acquired. When the start button 154 is selected, the maximum and minimum measurement values are displayed in real time. The reset button 156 is used to reset the measurement values.

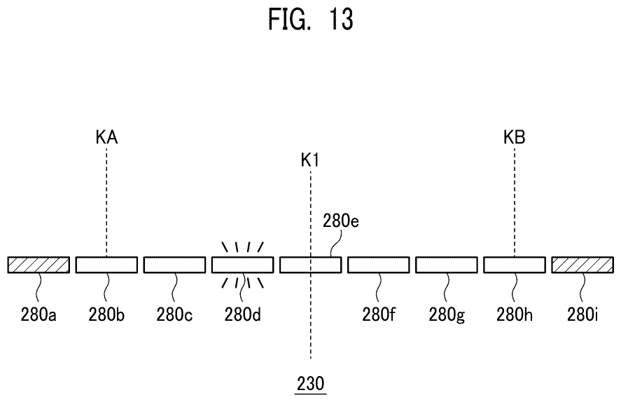

The dial mode screen 130 further displays an indicator 230. The indicator 230 visually indicates whether the lever 202 is within the valid measurement range and how close it is to the reference position. The indicator 230 is explained in detail in connection with FIG. 13 and beyond.

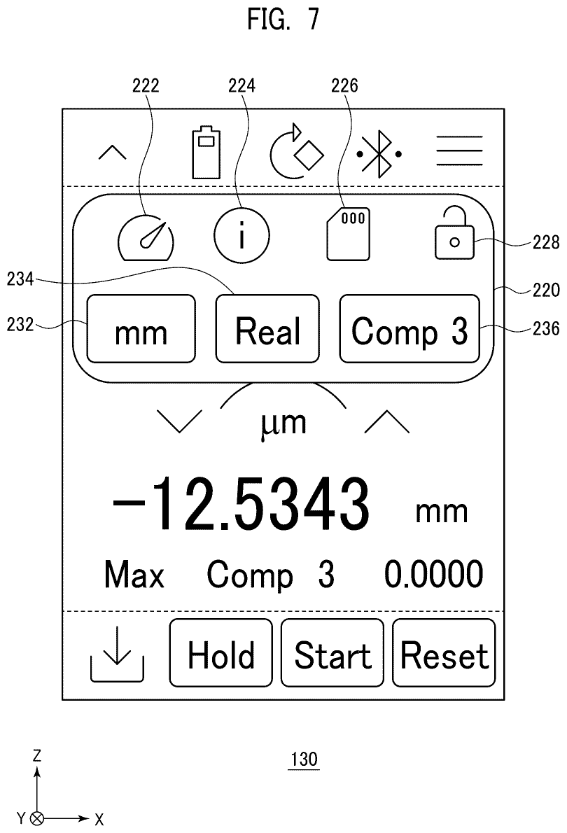

FIG. 7 is a second screen view of the dial mode screen 130.

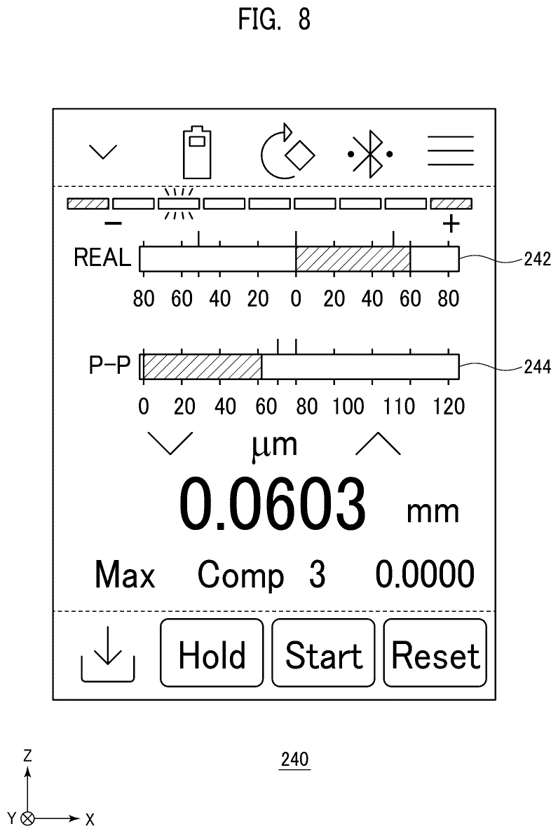

When the extension button 140 on the dial mode screen 130 is touched, the display control unit 126 displays the extended area 220. As shown in FIG. 7, the extended area 220 is displayed so that it is superimposed on the measurement area 134, or in other words, it is not superimposed on the icon area 138. Therefore, operability in the icon area 138 is maintained even when the extended area is displayed. The extended area 220 includes seven icons (mode button 222, device information button 224, card button 226, lock button 228, measurement unit button 232, measurement display button 234, and comparison button 236). The mode button 222 is an operation button for switching modes, which are ways of displaying measurement values. Modes other than the dial mode are explained in relation to FIG. 8 and beyond. The mode can be switched each time the mode button 222 is touched. More specifically, each time the mode button 222 is touched, the icon of the mode button 222 changes, and the display mode in the measurement area 134 also changes.

The device information button 224 is for displaying the setting information of the display device 100. The card button 226 is for removing the micro SD card. The lock button 228 is for locking the screen. When the screen is locked, the start button 154 and the reset button 156 are disabled.

The measurement unit button 232 is for changing the unit of measurement. The measurement display button 234 is for switching the measurement values to be displayed. The measurement value is specifically displayed by one of “REAL”, which indicates the real-time measurement value, “MAX”, which indicates the maximum value in the measurement period, “MIN”, which indicates the minimum value in the measurement period, and “PP”, which indicates the range between the maximum and minimum values. The comparison button 236 is for selecting one of several tolerance ranges that are set in advance. The tolerance range indicates the range that is acceptable as a measurement value.

The extended area 220 may be displayed in a position or size that is superimposed on the measurement area 134 and the icon area 138. Alternatively, when the extension button 140 on the dial mode screen 130 is touched, the display control unit 126 may extend the measurement area 134 and additionally display the seven icons included in the extended area 220 in the extended measurement area 134.

When the extension button 140 is touched, the extended area 220 including the mode button 222 and other buttons is displayed as described above. If the extension button 140 is touched again after selecting the dial mode, the display control unit 126 hides the extended area 220 including the mode button 222 and other buttons.

FIG. 8 is a screen view of a bar mode screen 240.

When the user selects “bar mode” with the mode button 222, the display control unit 126 displays the bar mode screen 240. When the user touches the mode button 222 once while in dial mode (see FIG. 7), the display control unit 126 changes the display mode from dial mode to bar mode. The mode switches cyclically in the order of dial mode, bar mode, numeric mode, chart mode, and simple circularity measurement mode. The bar mode screen 240 includes a current value bar 242 and a PP value bar 244. The PP value bar 244 indicates the displacement amount from the reference position K1 as a bar chart. When the displacement amount exceeds the tolerance range, the display control unit 126 changes the bar from a normal color, such as green, to a specific color, such as red, to indicate to the user that “the displacement amount is unacceptable”.

The PP value bar 244 indicates the range of change in the measurement value over a predetermined measurement period, e.g., from the start of the measurement to the current point in time. When the range of change exceeds the tolerance range, the display control unit 126 warns the user by changing the bar from a normal color, such as orange, to a specific color, such as red,

When the extension button 140 is touched, the extended area 220 is displayed. When the extension button 140 is touched while in dial mode, the extended area 220 displays the mode button 222, which indicates that the device is in dial mode. When the mode button 222 is touched in this state, dial mode is changed to bar mode. The mode button 222, which indicates that the device is in bar mode, is also displayed. After changing to bar mode, if the user touches the extension button 140, the extended area 220 is hidden, and the bar mode screen 240 shown in FIG. 8 is displayed.

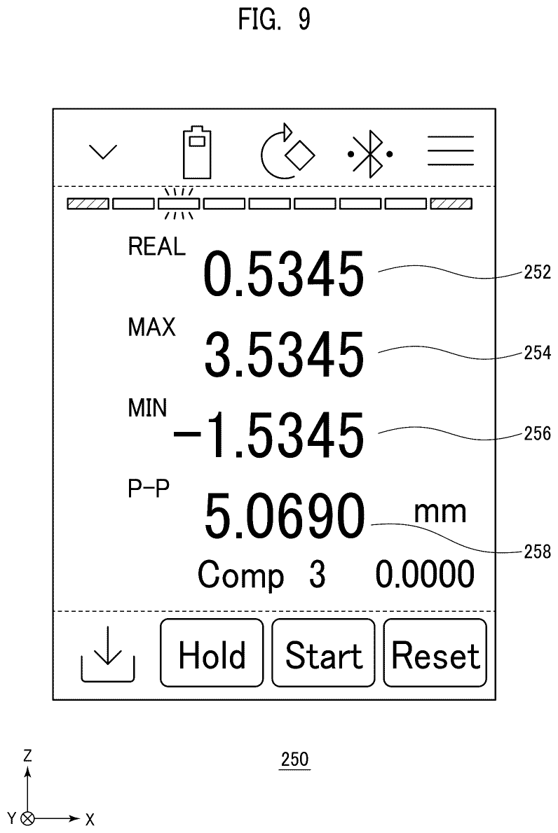

If the extension button 140 is touched while in bar mode, the extended area 220 displays the mode button 222, which indicates that the device is in bar mode. When the mode button 222 is touched in this state, bar mode is changed to numeric mode. The mode button 222, which indicates that the device is in numeric mode, is also displayed. After changing to numeric mode, if the user touches the extension button 140, the extended area 220 is hidden and the next numeric mode screen 250 shown in FIG. 9 is displayed.

The method of switching to numeric mode and beyond is the same.

FIG. 9 is a screen view of the numeric mode screen 250.

When the user selects “numeric mode” with the mode button 222, the display control unit 126 displays the numeric mode screen 250. The numeric mode screen 250 includes a REAL numeric value area 252, a MAX numeric value area 254, a MIN numeric value area 256, and a PP numeric value area 258. The REAL numeric value area 252 displays the latest measurement value. Usually, the lever gauge 200 transmits displacement signals corresponding to the latest measurement value at a high frequency so that the measurement value displayed in the REAL numeric value area 252 is also updated at a high frequency. The MAX numeric value area 254 indicates the maximum measurement value during the measurement period. The MIN numeric value area 256 indicates the minimum measurement value during the measurement period. The PP numeric value area 258 indicates the range between the maximum and minimum values of the measurement values during the measurement period. The display control unit 126 indicates the four measurement values by white numeric values. When the measurement value exceeds the tolerance range, the display control unit 126 changes the display color of the measurement values from white to red. Thus, in numeric mode, multiple numeric values indicating the measurement results in multiple formats are displayed side by side in a list.

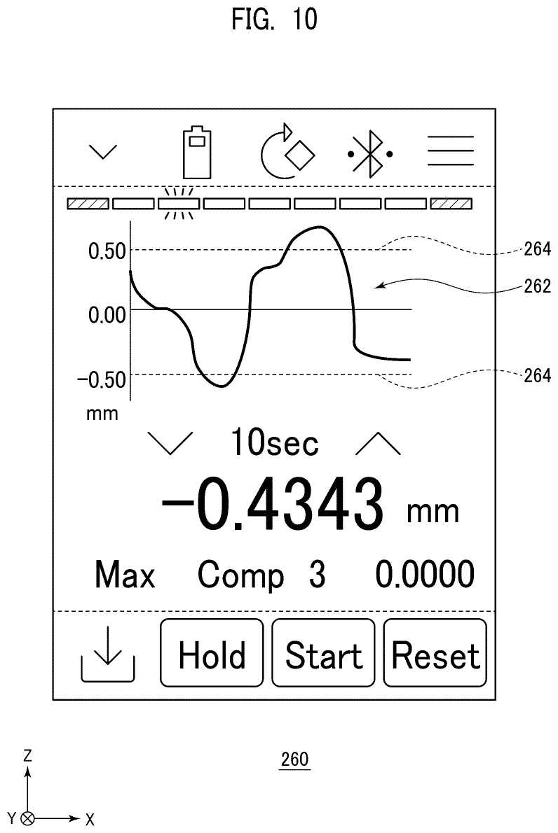

FIG. 10 is a screen view of a chart mode screen 260.

When the user selects “chart mode” with the mode button 222, the display control unit 126 displays the chart mode screen 260. The chart mode screen 260 includes a chart area 262. The horizontal axis of the chart area 262 indicates time, and the vertical axis indicates measurement values (REAL values). The chart area 262 shows the time variation of the measurement values during the measurement period. The display control unit 126 also indicates the tolerance range by dotted lines 264.

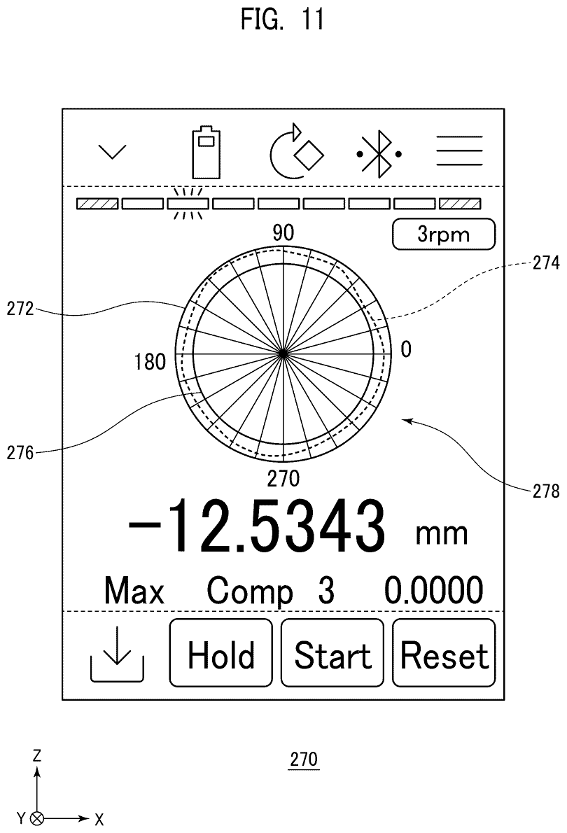

FIG. 11 is a screen view of a circularity measurement mode screen 270.

When the user selects “circularity measurement mode” with the mode button 222, the display control unit 126 displays the circularity measurement mode screen 270. The circularity measurement mode screen 270 includes a circularity measurement area 278. In the circularity measurement mode, the difference between the circular structure 210 and a perfect circle is measured by measuring the change in the outer diameter of the circular structure 210 while rotating the circular structure 210. For example, assume that the rotary table 212 rotates the circular structure 210 one revolution in 60 seconds. In this case, the rotation angle per second of the circular structure 210, i.e., angular velocity, is 6 (degrees/second).

If the lever gauge 200 is capable of performing a measurement 10 times per second, the display device 100 would obtain a measurement value for every 0.6 degrees of rotation of the circular structure 210. The display control unit 126 plots the measurement values obtained for each 0.6 degree of rotation on the circularity measurement area 278, thereby drawing a measurement circle 274. The measurement circle 274 is a continuous complement of the measurement values at each measurement point of the circular structure 210. The widths between the minimum circle 276 and maximum circle 272 correspond to the tolerance range.

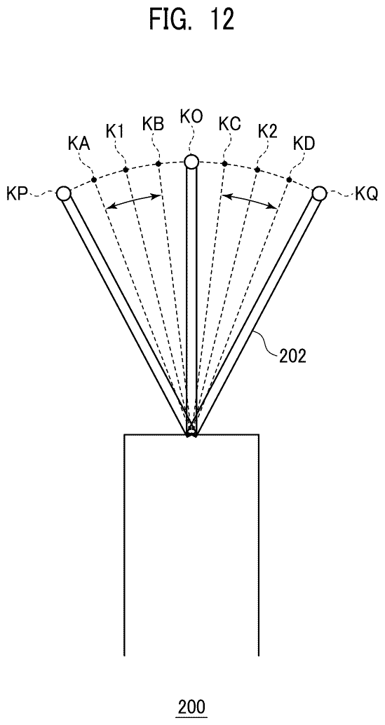

FIG. 12 is a schematic diagram to explain the movable range of the lever 202 in the lever gauge 200.

In the initial state, the extending direction of the lever 202 and the extending direction of the lever gauge 200 coincide (see FIG. 1). The initial position of the lever 202 at this time is denoted by “K0”. The lever 202 can be displaced up and down around the initial position K0. The maximum displacement position of the lever 202 in the upward direction (second direction) is denoted by “KP”, and the maximum displacement position in the downward direction (first direction) is denoted by “KQ”. In other words, the lever 202 can be displaced within the range of KP-KQ (hereinafter referred to as “movable range”).

In the movable range, some ranges can be measured with relatively high accuracy, while others can be measured with relatively accuracy. Usually, in the upward direction between the initial position K0 and the maximum displacement position KP, the lever gauge 200 has a valid measurement range of interval KA-KB where a high measurement accuracy can be guaranteed. The center of the interval KA-KB is set as the reference position K1. In the downward direction between the initial position K0 and the maximum displacement position KQ, the lever gauge 200 also has a valid measurement range of interval KC-KD where a high measurement accuracy can be guaranteed. The center of the interval KC-KD is set as the reference position K2. The user may set any displacement position in the valid measurement range as the initial setting position. In this embodiment, the reference position K1 or K2 is assumed to be the initial setting position.

When the lever 202 is displaced upward from the reference position K1 (above the initial position K0), measurement accuracy above a certain level can be guaranteed up to the upper boundary position KA. Similarly, when the lever 202 is displaced downward from the reference position K1, measurement accuracy above a certain level can be guaranteed down to the lower boundary position KB. The valid measurement range as the range where measurement accuracy above a certain level can be guaranteed includes the reference position K1 and is bounded by the upper boundary position KA and the lower boundary position KB. Similarly, the valid measurement range including the reference position K2 is bounded by the upper boundary position KC and the lower boundary position KD. Thus, the lever gauge 200 has two valid measurement ranges in the downward direction (second direction) and the upward direction (first direction) with respect to the initial position K0.

For the valid measurement range, which is determined by the structure of the lever gauge 200, it is difficult for the user to know where the valid measurement range and, in particular, the reference positions K1 and K2, are located. In general, the user fixes the lever gauge 200 with the lever 202 pressed against the workpiece so that it is slightly displaced from the initial position K0, and the position at that time is used as the “initial setting position”. The workpiece surface is then measured while moving the workpiece as illustrated in FIG. 4. If the initial setting position, which is slightly displaced from the initial position K0, is within the valid measurement range, high measurement accuracy can be expected. In general, the user often determines the initial setting position by exploring the valid measurement range, in particular the reference positions K1 and K2, from the sensation transmitted to the hand when the lever 202 is pressed against the workpiece. However, this method of exploring the initial setting position is very difficult for inexperienced users. In the following, it is assumed that the reference position K1 or K2 is the initial setting position.

FIG. 13 illustrates an example of the display of an indicator 230 during the reference position exploration.

The indicator 230 includes nine boxes 280 from a box 280a to a box 280i (see FIG. 6). The central box 280e corresponds to the reference position. When the user displaces the lever 202 upward, the central box 280e corresponds to the reference position K1, the box 280b corresponds to the upper boundary position KA, and the box 280h corresponds to the lower boundary position KB. Therefore, the boxes 280b through 280h correspond to the valid measurement range in the upper side from the initial position K0.

The display control unit 126 illuminates the box 280 corresponding to the position of the lever 202 out of the nine boxes 280 included in the indicator 230. In FIG. 13, the box 280d, one box to the left of the box 280e, is illuminated. By checking the indicator 230, the user can visually recognize that the current displacement amount of the lever 202 is slightly above the reference position K1. When determining the initial setting position of the lever 202, the user can set the lever at the initial setting position near the reference position K1 by adjusting the displacement amount of the lever 202 so that the box 280e is illuminated in the indicator 230. The initial setting position does not have to coincide with the reference position K1; the initial setting position should at least be within the valid measurement range. As described above, the displacement amount of the lever 202 from the initial setting position is the quantity to be measured.

On the other hand, when the user displaces the lever 202 downward, the center box 280e corresponds to the reference position K2, the box 280b corresponds to the upper boundary position KC, and the box 280h corresponds to the lower boundary position KD. Therefore, the boxes 280b through 280h correspond to the lower valid measurement range. When using the lower valid measurement range as well, the user may adjust the displacement amount of the lever 202 so that the box 280e is illuminated, and then determine the initial setting position of the lever gauge 200.

The lever gauge 200 and the display device 100 have been described above based on the embodiments.

According to the display device 100, measurement values can be displayed in various modes according to the purpose of measurement. For example, the numeric mode screen 250 can be displayed when the user wants to check the measurement value numerically, and the dial mode screen 130 can be displayed when the user wants to grasp the displacement amount of the lever 202 intuitively. In addition, the circularity of the circular structure 210 can be measured simply in this embodiment. In general, when measuring the outer diameter of a circular structure 210, the rotation angle of the circular structure 210 at the time of measurement is often acquired with an encoder, and the measurement value and the rotation angle are correspondingly recorded. In this embodiment, the circular structure 210 is rotated at a constant speed, and the rotation angle at the time of measurement can be determined by the time elapsed from the start of measurement.

According to the display device 100 in this embodiment, the reference position of the lever gauge 200 can be visually confirmed. Even a user who is not accustomed to the tactile sensation of the lever gauge 200 can easily measure the workpiece appropriately with the lever gauge 200.

The present invention is not limited to the embodiment described above and modifications thereof, and any component thereof can be modified and embodied without departing from the scope of the invention. Components described in the embodiment and modifications can be combined as appropriate to form various embodiments. Some components may be omitted from the components presented in the embodiment and modifications.

### Modifications

In this embodiment, the explanation assumes a form in which the lever gauge 200 is connected to the display device 100. However, the display device 100 may also be connected to other types of measuring instruments, such as indicator gauges.

This application claims priority from Japanese Patent Application No. 2022-143589 filed on Sep. 9, 2022, the entire contents of which are hereby incorporated by reference herein.

1. A display device, comprising:
a display unit; and
a display control unit that controls images displayed on the display unit, wherein
when one of a plurality of modes with mutually different ways of displaying measurement results is selected by using a mode button displayed on the display unit, the display control unit displays a measurement result on the display unit in a mode corresponding to the selected mode, and
the plurality of modes include at least:
(i) a dial mode that displays an image of a scale and a pointer superimposed thereon to display a value indicated by the pointer; and
(ii) a numeric mode that displays at least a measurement value, a maximum measurement value within a given period, and a minimum measurement value within the given period.

2. The display device according to claim 1, wherein the display control unit changes the range of the scale displayed on the display unit in the dial mode based on a range change instruction from a user, and
the display control unit displays an image on the display unit in the dial mode so as to show the range in which the pointer has moved.

3. The display device according to claim 1, wherein the plurality of modes further include a circularity measurement mode that shows the result of circumference measurement of a circular structure.

4. The display device according to claim 1, wherein the plurality of modes further include a chart mode that shows a history of changes in measurement values.

5. The display device according to claim 1, wherein the plurality of modes further include a bar mode that shows both or either of a measurement value and a range of change in the measurement value as a bar graph.

6. The display device according to claim 1, wherein the display unit includes a first area for displaying an image corresponding to the mode and a second area for displaying icons for operation, and
the display control unit (i) displays the mode button on the display unit when the icon is selected, and (ii) erases the mode button from the display unit when the dial mode is selected and the icon is selected after the mode button is displayed.
